(19) United States
(12) Patent Application Publication
(10) Pub. No.: US 2005/0183763 A1
(43) Pub. Date: Aug. 25, 2005

(54) Thermoelectric generation system utilizing a printed-circuit thermopile

(76) Inventor: Roger Christiansen, Yuma, AZ (US)

Correspondence Address: Jordan M. Meschkow;Meschkow & Gresham, PLC, Suite 409, 5727 North Seventh Street, Phoenx, AZ, 85014, US

(21) Appl. No.: 10/786,412

(22) Filed: Feb. 24, 2004

(51) Int. Cl. H01L 35/28; H01L 35/30

(52) U.S. Cl. 136/224

(57) ABSTRACT

A thermoelectric generation system (26) is presented. A plurality of PC thermopiles (24), each consisting of a substrate having a plurality of thermocouples (TC), are coupled together by a backplane (42) to form a thermoarray (TA) capable of producing a desired voltage (E_{TA}) at a desired current (I_{TA}). Each thermocouple (TC) is formed of a first trace (28) formed of a first conductor (20) upon a first surface (32) of the substrate (30) and a second trace (34) formed of a second conductor (22) upon a second surface (36) of the substrate (30). A first junction (J₁) formed between the first and second traces (28,34) is maintained at substantially a first temperature (T₁), and a second junction (J₂) formed between the first and second traces (28,34) is maintained at substantially a second temperature (T₂), so that each thermocouple (TC) generates a voltage (E_{TC}) and a current (I_{TC}) These voltages (E_{TC}) and currents (I_{TC}) are concatenated to achieve the desired voltage (E_{TA}) and current (I_{TA})

### TECHNICAL FIELD OF THE INVENTION

The present invention relates to the field of electrical generation. More specifically, the present invention relates to the field of electrical generation utilizing the Seebeck effect.

### BACKGROUND OF THE INVENTION

A majority of electrical generation systems conventionally use mechanical energy to drive a magnetic generator and produce the desired electrical energy. This mechanical energy may be natural or produced, but in all case requires conversion prior to use. This conversion of energy results in a marked loss of efficiency in such a system.

In thermo-mechanical generation systems, thermal energy is used to produce steam. The steam in turn drives a turbine to produce rotary mechanical energy. The rotary mechanical energy is then used to drive a conventional magnetic generator to produce the electricity. Since each step in this process has losses, the resultant electrical energy represents only a fraction of the applied thermal energy. The thermal energy required of a thermo-mechanical generation system may be produced by the burning of a fossil or nuclear fuel, obtained from the concentration of solar energy, or obtained directly from geothermal activity. The source of the thermal energy for a thermo-mechanical generation system is irrelevant to the generation process.

In “natural” mechanical generation systems, a substantially linear or reciprocation mechanical energy is applied to a turbine to produce the requisite rotary mechanical energy to drive the conventional magnetic generator. Examples of “natural” mechanical generation systems are hydrodynamic, wind, and tidal systems.

A problem with all such mechanical generation systems is that they are mechanical and complex. That is, they contain moving parts and often require a sophisticated infrastructure for operation. With a conventional fossil-fuel generation system, the generation system comprises a sophisticated concatenation of mechanical systems is required. In addition, a highly complex infrastructure for the acquisition and shipment of the fossil fuel, and of the disposal of the resultant “ash,” is required above and beyond the generation system itself.

Solar photovoltaic generation systems have no moving parts and therefore present a viable alternative source of electrical energy. Unfortunately, solar systems of all types are subject to diurnal, climatological, and meteorological limitations. Because of this, solar system typically have electrochemical storage devices (e.g., batteries) to compensate for the day-night cycle, the changing of the seasons, and adverse weather. These devices, while not having the complex moving parts of the mechanical systems, have their own limitations and problems.

Ideally, an electrical generation system should be simple in structure, have no moving parts, and be immune to diurnal, climatological, and meteorological effects.

### SUMMARY OF THE INVENTION

Accordingly, it is an advantage of the present invention that a thermoelectric generation system utilizing a printed-circuit thermopile is provided.

It is another advantage of the present invention that a thermoelectric generation system is provided that is immune to diurnal, climatological, and meteorological effects.

It is another advantage of the present invention that a thermoelectric generation system is provided that has no moving parts.

It is another advantage of the present invention that a thermoelectric generation system is provided that is readily adaptable to variant energy needs.

The above and other advantages of the present invention are carried out in one form by a printed-circuit thermopile formed of a printed-circuit substrate having a first surface and a second surface, and having a first thermal portion and a second thermal portion, a plurality of first traces, wherein each of the first traces is formed of a first metal and extends between the first and second thermal portions upon the first surface, a plurality of second traces, wherein each of the second traces is formed of a second metal and extends between the first and second thermal portions upon the second surface, a plurality of first junctions, wherein each of the first junctions couples one of the first traces with one of the second traces in the first thermal portion, and a plurality of second junctions, wherein each of the second junctions couples one of the first traces with one of the second traces in the second thermal portion, and wherein each of the second junctions is in series with one of the first junctions.

The above and other advantages of the present invention are carried out in one form by a thermoelectric generation system configured to provide electrical energy at a predetermined voltage and current, and incorporating a plurality of printed-circuit thermopiles and a backplane coupled to and configured to electrically connect the thermopiles to provide the electrical energy.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, and:

FIG. 1 shows a schematic view of a closed-loop type-T thermocouple;

FIG. 2 shows a chart depicting a temperature versus output curve for a type-T thermocouple;

FIG. 3 shows a schematic view of a static model of the closed-loop thermocouple of FIG. 1;

FIG. 4 shows a schematic view of an open-loop type-T thermocouple;

FIG. 5 shows a schematic view of a static model of a the open-loop thermocouple of FIG. 3 under load;

FIG. 6 shows a schematic view of a series thermopile in accordance with a preferred embodiment of the present invention;

FIG. 7 shows a schematic view of a parallel thermopile in accordance with a preferred embodiment of the present invention;

FIG. 8 shows a schematic view depicting a composite thermopile in accordance with a preferred embodiment of the present invention;

FIG. 9 shows a schematic view of an exemplary thermopile in accordance with a preferred embodiment of the present invention;

FIG. 10 shows a front view of a printed-circuit thermopile in accordance with a preferred embodiment of the present invention;

FIG. 11 shows an end view of a plurality of printed-circuit thermopiles arranged as a thermoelectric generation system in accordance with a preferred embodiment of the present invention;

FIG. 12 shows a cross-sectional view of the printed-circuit thermopile of FIG. 10 taken at line 12-12 and demonstrating an overlap junction in accordance with a first preferred embodiment of the present invention;

FIG. 13 shows a cross-sectional view of the printed-circuit thermopile of FIG. 10 taken at line 12-12 and demonstrating a filled junction in accordance with a second preferred embodiment of the present invention;

FIG. 14 shows a cross-sectional view of the printed-circuit thermopile of FIG. 10 taken at line 12-12 and demonstrating a pin junction in accordance with a third preferred embodiment of the present invention; and

FIG. 15 shows a cross-sectional view of the printed-circuit thermopile of FIG. 10 taken at line 12-12 and demonstrating a heat-sink junction in accordance with a fourth preferred embodiment of the present invention.

### DETAILED DESCRIPTION OF THE PREFERRED EMBODIMENTS

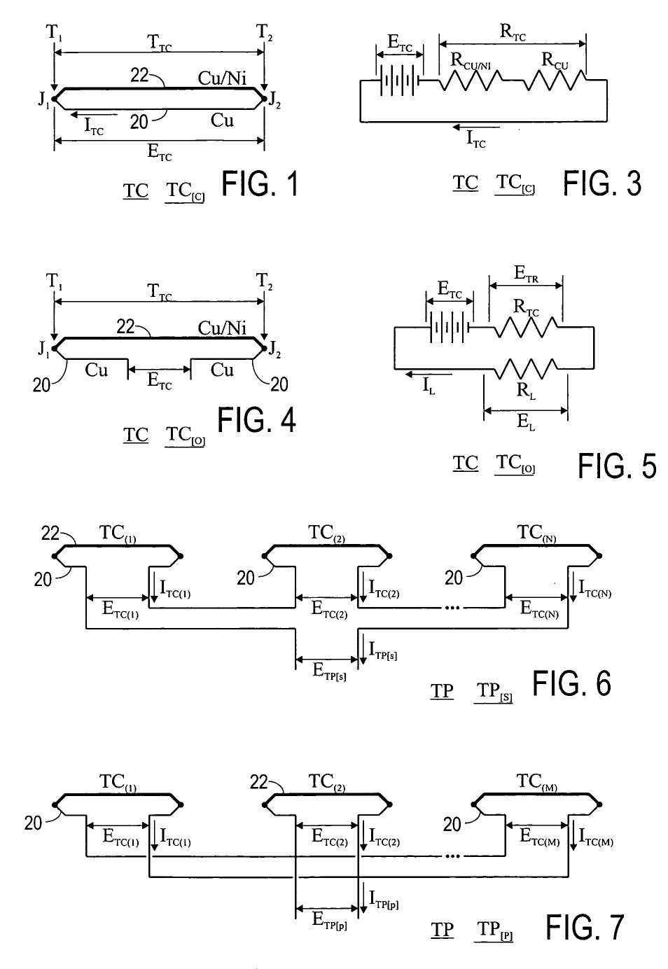

FIG. 1 shows a schematic view of a type-T closed-loop thermocouple TC_{[C]}. In its simplest form, a thermocouple TC is made up of a first conductor 20 formed of a first metal and a second conductor 22 formed of a second, dissimilar metal. First and second conductors 20 and 22 are joined at one end to form a first junction J₁, and at the other end to form a second junction J₂. Thermocouple TC therefore forms a closed loop, i.e., is a closed-loop thermocouple TC_{[C]}.

In the preferred embodiment of FIG. 1, thermocouple TC is a type-T or copper-constantan thermocouple. That is, first conductor 20 is formed of copper (Cu), and second conductor 22 is formed of the copper-nickel alloy constantan (Cu/Ni). Those skilled in the art will appreciate, however, that a copper-constantan thermocouple is not a requirement of the present invention, and that other materials may be used for either first or second conductor 20 or 22 without departing from the spirit of the present invention.

When first junction J₁ is at a first temperature T₁ and second junction J₂ is at a second temperature T₂, then a voltage E_{TC} is generated between first and second junctions J₁ and J₂. This generation of voltage E_{TC} is known as the Seebeck effect. The value of voltage E_{TC} is a function of:
T_{TC}=|T₁−T₂|, and (1)
E_{TC}=S×T_{TC}, (2)
where:
E_{TC} is the differential temperature across thermocouple TC; and
S is the Seebeck coefficient for thermocouple TC.

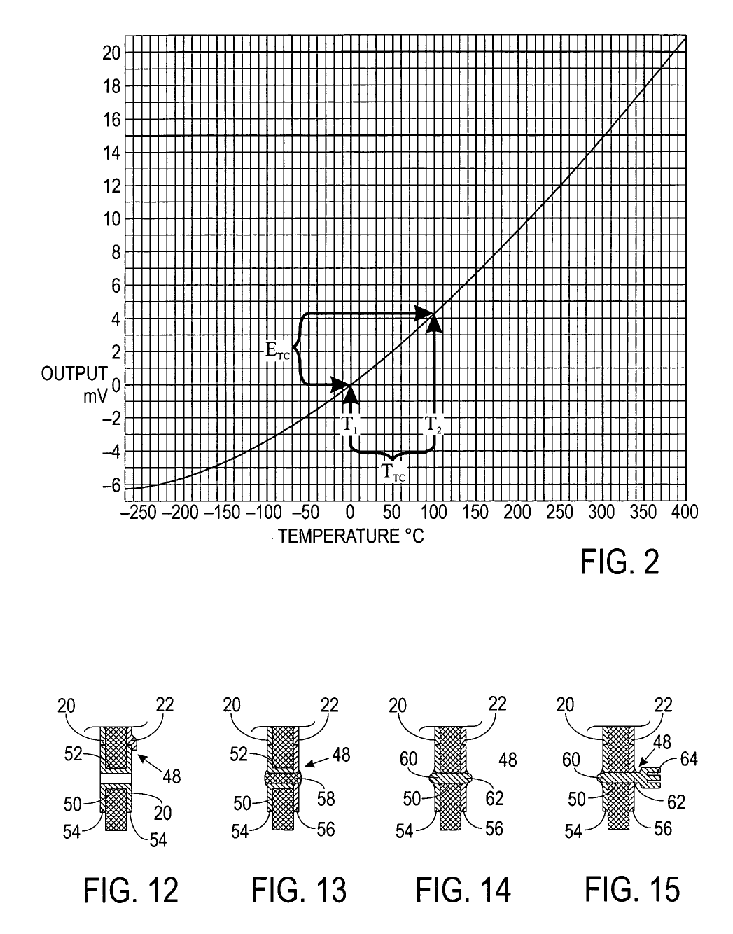

FIG. 2 shows a chart depicting a temperature versus output curve for thermocouple TC. The following discussion refers to FIGS. 1 and 2.

Seebeek coefficient S for a given thermocouple type changes with temperature. However, for a given thermocouple TC, coefficient S may be approximately linear for a given differential temperature T_{TC}.

In FIG. 2 it may be seen that, when first junction J₁ is at a first temperature T₁ of 0° C. and second junction J₂ is at a second temperature T₂ of 100° C., a type-T thermocouple TC has a differential temperature T_{TC} of 100° C. and produces a voltage E_{TC} of 4.279 mV. Over this range, therefore, coefficient S is ≈42.79 μV/° C.

In the preferred embodiment, thermocouple TC is a type-T copper-constantan thermocouple. A type-T thermocouple is formed of copper and constantan. Copper is an elemental metal having a low electrical resistivity. Constantan (a.k.a. 55/45 constantan, ferry, hecnum, and telconstan) is an alloy of 53.8% copper, 44.2% nickel, 1.5% manganese, and 0.5% iron, having a high electrical resistance and a low temperature coefficient. Copper and constantan have the relevant characteristics depicted in table 1:

TABLE 1
Characteristics of Copper and Constantan

| Property @ 20° C. | Copper | Constantan | Units |
|---|---|---|---|
| Temperature Coefficient | +0.0043 | ±0.00002 | K⁻¹ |
| Electrical Resistivity | 1.69 | 52.0 | μΩ cm |
| | 10.164 | 312.75 | Ω/CMF |
| Density | 8.96 | 8.9 | g cm⁻³ |
| Coefficient of Thermal Expansion | 17.0 | 14.9 | ×10⁻⁶ K⁻¹ |
| Thermal Conductivity | 401 | 19.5 | W m⁻¹ K⁻¹ |

With the understanding that other type of thermocouples and/or other temperatures may be used, this discussion will hereinafter assume for the sake of simplicity that thermocouple TC is a type-T copper-constantan thermocouple, that first conductor 20 is formed of copper, that second conductor 22 is formed of constantan, that first junction J₁ is at a first temperature T₁ of 0° C., that second junction J₂ is at a second temperature T₂ of 100° C., that differential (thermocouple temperature T_{TC} is 100° C., and that thermocouple voltage E_{TC} is 4.279 mV.

FIG. 3 shows a schematic view of a static model of closed-loop thermocouple TC_{[C]}. The following discussion refers to FIGS. 1 and 3.

Since thermocouple TC_{[C]} is a closed loop with voltage E_{TC} expressed between junctions J₁ and J₂, thermocouple TC_{[C]} represents a closed circuit. Voltage E_{TC} causes a current I_{TC} to flow through this closed circuit, i.e., through thermocouple TC_{[C]}. By Ohm's law:

$${I}_{TC} = \frac{{E}_{TC}}{{R}_{TC}} = \frac{{E}_{TC}}{{R}_{Cu} + {R}_{Cu / Ni}} , \qquad ( 3 )$$

where:
R_{TC} is the resistance of thermocouple TC_{[C]};
R_{Cu} is the resistance of copper conductor 20, and
R_{Cu/Ni} is the resistance of constantan conductor 22.

As discussed hereinbefore, copper has a resistivity of 1.69 μΩ cm (i.e., 1.69×10⁻⁶ ohms for a conductor having a cross-section area of 1 square centimeter and a length of 1 centimeter). This equates to 10.164 Ω/CMF (i.e., 10.164 ohms for a conductor having a cross-sectional area of 1 circular mil and a length of 1 foot). Similarly, constantan has a resistivity of 52.0 μΩ cm or 312.75 Ω/CMF. This means that constantan has approximately 30.8 times the resistivity of copper.

FIG. 4 shows a schematic view of an open-loop type-T thermocouple TC_{[0]}, and FIG. 5 shows a schematic view of a static model of an open-loop thermocouple TC_{[0]} under load. The following discussion refers to FIGS. 1, 2, 4, and 5.

A closed-loop thermocouple TC_{[C]} serves no purpose (other than an instructional purpose) because both voltage E_{TC} and current I_{TC} are isolated from the real world. However, if either of first or second conductors 20 or 22 is opened, closed-loop thermocouple TC_{[C]} becomes open-loop thermocouple TC_{[0]}.

Open-loop thermocouple TC_{[0]} represents an open circuit. There is, therefore, no current I_{TC} flowing through open-loop thermocouple TC_{[0]} (as depicted in FIG. 4). Since there is no current I_{TC}, voltage E_{TC} is present at the ends of the opened conductor. A theoretical infinite-resistance voltage-measuring device (not shown) could be coupled to the opened ends and measure voltage E_{TC}. Having an infinite resistance, the voltage-measuring device does not close the circuit through thermocouple TC_{[0]} and current I_{TC} remains at zero. The voltage-measuring device could then determine voltage E_{TC} with great accuracy. The Seebeck effect for specific thermocouples is well known. Therefore, differential thermocouple temperature T_{TC} may also be determined with great accuracy. If one of the junction temperatures T₁ or T₂ is known, then the other may be determined. For example, if temperature T₁ of junction J₁ is known to be 0° C. and thermocouple voltage E_{TC} is measured to be 4.279 mV, then temperature T₂ of junction J₂ must be 100° C. Indeed, use as a temperature-measuring device is the most common conventional use of thermocouple TC.

Those skilled in the art will appreciate that an infinite-resistance voltage measuring device does not exist, and that, in practice, the voltage measuring device must have some resistance. Since it is desirable that the measuring device measure voltage E_{TC} as accurately as possible, it is desirable that the resistance of the measuring device, a load resistance R_{L} in FIG. 5, be as high as possible. A current I_{L} through a loaded thermocouple TC_{[L]} would then be a function of thermocouple resistance R_{TC} in series with load resistance R_{L}:

$${I}_{L} = \frac{{E}_{TC}}{{R}_{TC} + {R}_{L}} . \qquad ( 4 )$$

If load resistance R_{L} is very much (e.g., several orders of magnitude) higher than thermocouple resistance R_{TC}, then thermocouple resistance R_{TC} is negligible and current I_{L} becomes substantially a function of load resistance R_{L}:

$${I}_{L} = \frac{{E}_{TC}}{{R}_{TC} + {R}_{L}} ≅ \frac{{E}_{TC}}{{R}_{L}} . \qquad ( 5 )$$

Voltage E_{TC} is proportionately expressed across thermocouple resistance R_{TC} and load resistance R_{L} in series. By Kirchhoff's law, we know:
E_{TC}=E_{TR}+E_{L}, (6)
where:
E_{TR} is the voltage expressed across thermocouple resistance R_{TC}, and

E_{L} is the voltage expressed across load resistance R_{L}.

Since load resistance R_{L} is very much greater than thermocouple resistance R_{TC}, then thermocouple resistance R_{TC} is negligible:
E_{TC}=E_{TR}+E_{L}≅E_{L}, (7)

In the case of use as a measuring device, therefore, it is desirable to have current I_{L} through loaded thermocouple TC_{[L]} as low as possible. When thermocouple TC is to be used as an electrical generation device, however, it is desirable that the energy generated be as high as possible. This necessitates that, for a give voltage E_{TC}, current I_{TC} be as high as possible.

For a given loaded thermocouple TC_{[L]}, current I_{L} has a maximum value when load resistance R_{L} is zero, i.e., when thermocouple TC is a closed-loop thermocouple TC_{[C]}. It is therefore desirable that load resistance R_{L} be very much (e.g., several orders of magnitude) lower than thermocouple resistance R_{TC}. In this case, load resistance R_{L} becomes negligible and current I_{L} becomes substantially a function of thermocouple resistance R_{TC}:

$${I}_{L} = \frac{{E}_{TC}}{{R}_{TC} + {R}_{L}} ≅ \frac{{E}_{TC}}{{R}_{TC}} = {I}_{TC} . \qquad ( 8 )$$

For the sake of simplicity, the remainder of this discussion presumes that all thermocouples TC are type-T thermocouples having substantially identical resistances R_{TC}, that all temperatures T₁ are substantially identical, that all differential thermocouple temperatures T_{TC} are substantially identical, that all thermocouple voltages E_{TC} are substantially identical, and that all thermocouple zero-load currents I_{TC} are substantially identical. Furthermore, it is assumed that all load resistances R_{L} for any thermocouple TC or any combination of thermocouples TC is substantially zero. Those skilled in the art will appreciate that these conventions are exemplary only, and have no bearing in reality.

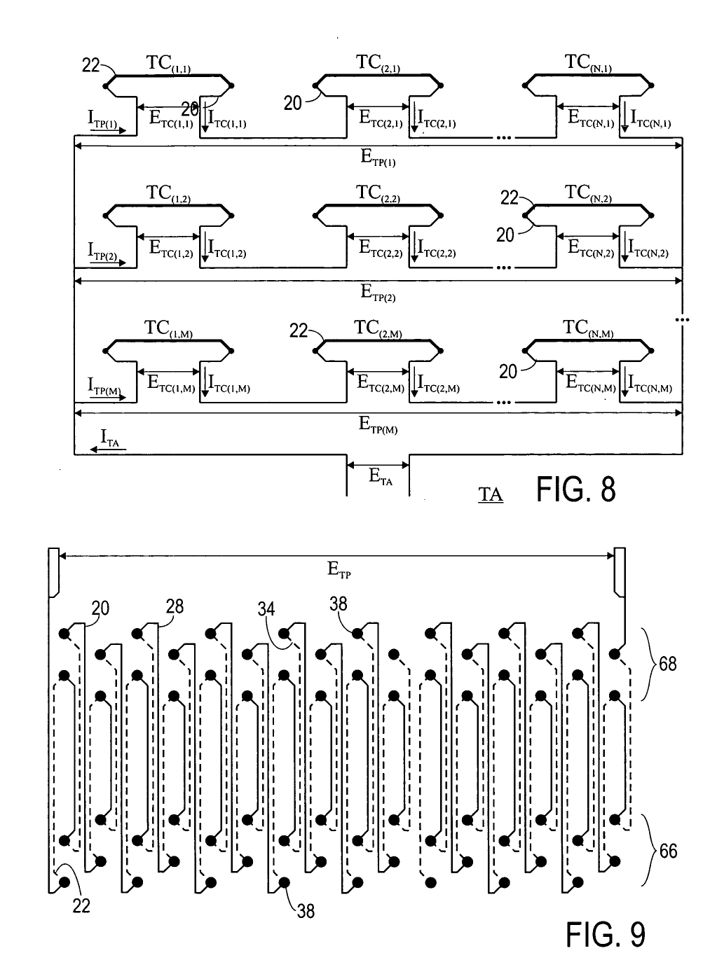

FIGS. 6, 7, and 8 show schematic views of thermopiles in accordance with a preferred embodiment of the present invention, where FIG. 6 depicts a series thermopile TP_{[S]}, FIG. 7 depicts a parallel thermopile TP_{[P]}, and FIG. 8 depicts a composite thermopile (thermoarray) TA. The following discussion refers to FIGS. 4 through 8.

Thermocouples TC may be concatenated to form a thermopile TP. FIG. 6 depicts N thermocouples TC₍ₙ₎ connected in series to form a series thermopile TP_{[S]}. Since thermocouples TC₍₁₎ through TC_{(N)} are connected in series, their voltages E_{TC(1)} through E_{TC(N)} are summed and their currents I_{TC(1)} through I_{TC(N)} are not:
E_{TP[S]}=E_{TC(1)}+E_{TC(2)}+ . . . +E_{TC(N)}, (9)
I_{TP[S]}=I_{TC(1)}=I_{TC(2)}= . . . =I_{TC(N)}, (10)
where:
N is an integer greater than 1,
n is an integer between 1 and N, inclusively,
E_{TC(n)} is the voltage of thermocouple TC₍ₙ₎,
I_{TC(n)} is the current of thermocouple TC₍ₙ₎,
E_{TP[S]} is the voltage of series thermopile TP_{[S]}, and
I_{TP[S]} is the current of series thermopile TP_{[S]}.

This means that for a given series thermopile TP_{[S]} having N thermocouples TC₍ₙ₎, thermopile voltage E_{TP[S]} is:
E_{TP[S]}=N×E_{TC(n)}, (11)
but the thermopile current I_{TP[S]} is limited to the current I_{TC(n)} of any one thermocouple TC₍ₙ₎.

Similarly, FIG. 7 depicts M thermocouples TC₍ₘ₎ connected in parallel to form a parallel thermopile TP_{[P]}. Since thermocouples TC₍₁₎ through TC_{(M)} are connected in parallel, their currents I_{TC(1)} through I_{TC(M)} are summed and their voltages E_{TC(1)} through E_{TC(M)} are not:
E_{TP[P]}=E_{TC(1)}=E_{TC(2)}= . . . =E_{TC(M)}, (12)
I_{TP[P]}=I_{TC(1)}+I_{TC(2)}+ . . . +I_{TC(M)}, (13)
where:
M is an integer greater than 1,
m is an integer between 1 and M, inclusively,
E_{TC(m)} is the voltage of thermocouple TC₍ₘ₎,
I_{TC(m)} is the current of thermocouple TC₍ₘ₎,
E_{TP[P]} is the voltage of parallel thermopile TP_{[P]}, and
I_{TP[P]} is the current of parallel thermopile TP_{[P]}.

This means that for a given parallel thermopile TP_{[P]} having M thermocouples TC₍ₘ₎, thermopile current I_{TP[P]} is:
E_{TP[P]}=M×E_{TC(m)}, (14)
but the thermopile voltage E_{TP[P]} is limited to the voltage E_{TC(m)} of any one thermocouple TC₍ₘ₎.

FIG. 8 depicts a composite thermopile (i.e., a thermoarray) TA of M thermopiles TP₍ₘ₎ connected in parallel, where each thermopile TP₍ₘ₎ contains N thermocouples TC_{(n,m)} connected in series. In this arrangement, a voltage E_{TA} of thermoarray TA is substantially equal to voltages E_{TP(m)} of each thermopile TP₍ₘ₎, where voltage E_{TP(m)} of each thermopile TP₍ₘ₎ is substantially equal to a sum of voltages E_{TC(n,m)} of each thermocouple TC_{(n,m)} in thermopile TP₍ₘ₎. Similarly, current I_{TA} of thermoarray TA is substantially equal to a sum of currents I_{TP(m)} of each thermopile TP₍ₘ₎, where current I_{TP(m)} of each thermopile TP₍ₘ₎ is substantially equal to current I_{TC(n,m)} of each thermocouple TC_{(n,m)} in thermopile TP₍ₘ₎. This may be expressed as:
E_{TA}=E_{TP(1)}=E_{TC(2)}= . . . =E_{TC(M)}, (15)
E_{TP(m)}=E_{TC(1,m)}+E_{TC(2,m)}+ . . . +E_{TC(N,m)}, (16)
I_{TA}=I_{TP(1)}+I_{TP(2)}+ . . . +I_{TP(M)}, and (17)
I_{TP(m)}=I_{TC(1,m)}=I_{TC(2,m)}= . . . =I_{TC(N,m)}. (18)

This means that for a given thermoarray TA containing M thermopiles TP₍ₘ₎ in parallel, with each thermopile TP₍ₘ₎ containing N thermocouples TC₍ₙ₎ in series, voltage E_{TA} and current I_{TA} of thermoarray TA are:
E_{TA}=N×E_{TC(n,m)}, (19)
I_{TA}=M×I_{TC(n,m)}. (20)

By creating a large enough thermoarray, any desired voltage E_{TA} and current I_{TA} may be supplied. In the preferred embodiment, for example, it is desirable that ≈165 Vdc at ≈21 A (i.e., ≈3.5 kW) be generated. To produce ≈165 V requires 38,560 thermocouples TC connected in series. Assuming, for the sake of discussion, that each thermocouple TC has a resistance of 10 mΩ, then each thermocouple is capable of producing 427.9 mA. To produce ≈21 A requires 49 thermocouples TC in parallel. To produce ≈165 V at ≈21 A therefore requires that thermoarray TA be an array of 1,889,440 (38,560×49) thermocouples TC. In practice, these numbers would most likely be rounded up to 2,000,000 (40,000×50) thermocouples TC.

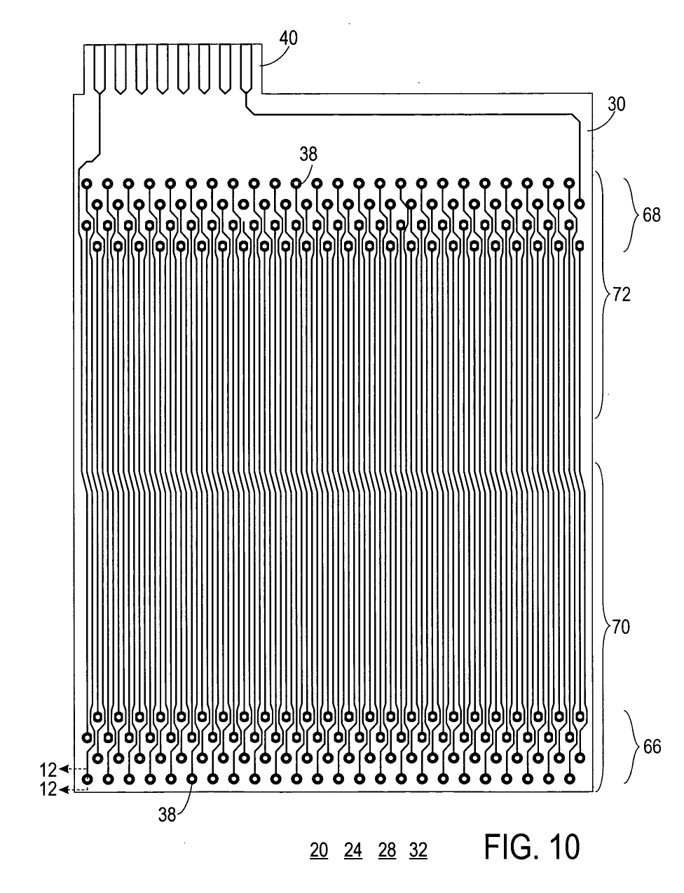

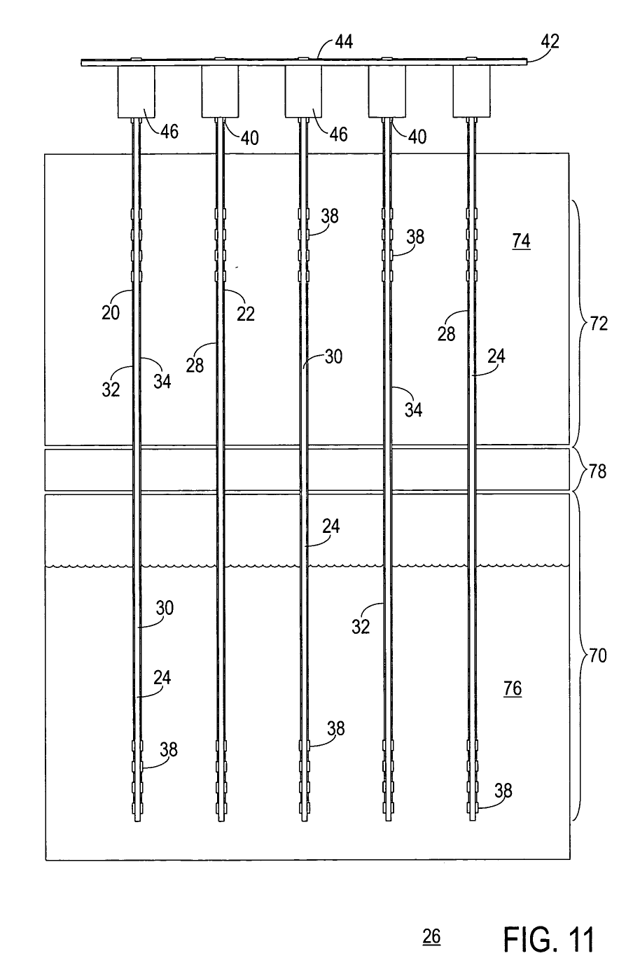

FIG. 9 shows a schematic view of an exemplary thermopile TP. FIG. 10 shows a front view of a printed-circuit (PC) thermopile 24, and FIG. 11 shows an end view of a plurality of PC thermopiles 24 arranged as a portion of a thermoelectric generation system 26 in accordance with a preferred embodiment of the present invention. The following discussion refers to FIGS. 4 and 8 through 11.

In order to make practical such a large thermoarray TA, it is desirable that thermopiles TP of very high density be realized. In the preferred embodiment, this is achieved through the use of a multiplicity of PC thermopiles 24.

Each PC thermopile 24 is desirably configured to have a high-density serial thermopile TP_{[S]} arranged upon a substrate 30. Desirably, PC thermopile 24 would have traces 28 of first conductor 20 upon a first surface 32 of substrate 30, and second traces 34 of second conductor 22 upon a second surface 36 of substrate 30, with through-substrate “pads” forming the requisite junctions J₁ and J₂ for each thermocouple. This approach is demonstrated schematically in FIG. 9, which is essentially an X-ray view of the traces. In FIG. 9, all solid lines represent first traces 28 on first surface 32, all dotted lines represent second traces 34 on second surface 36, and all solid dots represent couplings 38 (discussed in more detail hereinafter) which pass through substrate 30 and form junctions J₁ and J₂.

FIG. 10 depicts first surface 32 of an exemplary PC thermopile 24. When first traces 28 on first surface 32 are coupled with second traces 34 on second surface 36 (not shown in FIG. 10) through couplings 38, 96 serially-connected thermocouples TC will be formed as per FIG. 9. A board connector 40 at one edge of PC thermopile 24 provides a way to connect PC thermopiles 24 together.

Those skilled in the art will appreciate that FIG. 9 is highly simplified for clarity. In practice, it would be well within the current sate of the art to produce PC thermopile 24 with 1000 thermocouples TC. To produce PC thermopile 24 with any given number of thermocouples TC does not depart from the spirit of the present invention.

FIG. 11 depicts a plurality of PC thermopiles 24 coupled to a backplane 42 to form an exemplary portion of generation system 26. In the preferred embodiment of FIG. 11, backplane is made up of a printed circuit board 44 having a plurality of backplane connectors 46. In use, board connector 40 of one PC thermopile 24 is connected to each backplane connector 46. Backplane 42 contains traces (not shown) interconnecting PC thermopiles 24.

Those skilled in the art will appreciate that FIG. 11 is also highly simplified for clarity. In practice, backplane 42 may be one of a plurality of backplanes 42 interconnected to provide the desired thermoarray TA. For example, to produce the previously discussed array of 40,000×50 thermocouples TC when each PC thermopile 24 contains 1000 thermocouples TC, 50 backplanes 42 may be connected in parallel, where each backplane 42 has 40 backplane connectors 46 connected in series. This would allow each backplane connector 46 to be connected to one of 2000 PC thermopile 24, and would produce the desired array of 2,000,000 series/parallel thermocouples TC.

Those skilled in the art will appreciate that arrangements of thermocouples TC and PC thermopiles 24 other than those exemplified hereinbefore for the preferred embodiments may be realized without departing from the spirit of the present invention.

In FIGS. 10 and 11, connectors 40 and 46 are depicted as conventional PC edge-card connectors. Those skilled in the art will appreciate that this is exemplary only and that no specific connector type is required by the present invention. The use of other connector types does not depart from the spirit of the present invention.

FIGS. 12 through 15 show cross-sectional views of PC thermopile 24 taken at line 12-12 of FIG. 10 in accordance with alternative embodiments of the present invention. The following discussion refers to FIGS. 10 through 15.

FIG. 12 demonstrates the use of a plated-through hole and an overlap to form a physical junction 48 (i.e., either junction J₁ or J₂). In this embodiment, a hole 50 is made through substrate 30 at the desired location of each physical junction 48 (i.e., at the location of each junction J₁ and J₂). Each hole 50 is then plated with copper, thereby making each hole 50 a copper plated-through hole 52 that extends from first surface 32 to second surface 36. Copper traces 28, including copper pads 54, are then etched or deposited upon first surface 32 of substrate 30, while only copper pads 54 are etched or deposited upon second surface 36. Opposing copper pads 54 conductively combine with plated-through holes 52 to form couplings 38. Couplings 38 extend copper traces 28 from first surface 32 to second surface 36 of substrate 30. Constantan traces 34 are then deposited upon second surface 36 of substrate 30. Physical junctions 48 are formed at couplings 38 wherever constantan traces 34 come into contact with copper pads 54 upon second surface 36.

FIG. 13 demonstrates the use of a filled plated-through hole to form physical junction 48. In this embodiment, hole 50 is again made through substrate 30 and plated with copper to form a copper plated-through hole 52 extending from first surface 32 to second surface 36 at the desired location of each physical junction 48. Copper traces 28, including copper pads 54, are etched or deposited only upon first surface 32 of substrate 30. Constantan traces 34, including constantan pads 56, are etched or deposited upon second surface 36. Copper pads 54, plated-through holes 52, and constantan pads 56 together form couplings 38. Physical junctions 48 are formed within couplings 38 wherever constantan pads 56 come into contact with copper plated-through holes 52 at second surface 36.

Copper pads 54 on first surface 32 conductively combine with plated through holes 52. This is not necessarily the case with constantan pads 56, which may form weak electrical bonds with copper plated-through holes 52. This problem may be eliminated by filling plated-through holes with a connection conductor 58 (typically solder), which does form a strong electrical bond with both copper and constantan.

FIG. 14 demonstrates the use of a pin to form physical junction. In this embodiment, hole 50 is made through substrate 30, but not plated. Copper traces 28, including copper pads 54, are etched or deposited upon first surface 32 of substrate 30, and constantan traces 34, including constantan pads 56, are etched or deposited upon second surface 36. A pin 60 is passed through each hole 50 and electromechanically affixed to copper pads 54 upon first surface 32 and constantan pads 56 upon second surface 36 (typically by soldering). Pins 60 are formed of a pin conductor 62 (typically copper). Copper pads 54, pins 60, and constantan pads 56 together form couplings 38. Physical junctions 48 are formed wherever pins 60 come into contact with constantan pads 56.

FIG. 15 demonstrates the use of a pin incorporating a heat sink to form physical junction. This embodiment is substantially identical to the embodiment of FIG. 14 (discussed hereinbefore) save that pin 60 is extended and flared upon on side to form a heat sink 64. Heat sink 64 serves to better maintain the temperature of physical junction 48 at the temperature of the surrounding medium (discussed hereinafter). Those skilled in the art will appreciate that the shape of heat sink 64 is irrelevant to this discussion. The use of any given shape does not depart from the spirit of the present invention.

The following discussion refers to FIGS. 4, 8, 10 and 11.

In order for PC thermopile 24 to produce electricity, the junctions J₁ and J₂ of each thermocouple TC must be at different temperatures. On PC thermopile 24, junctions J₁ and J₂ are realized as physical junctions 48 located substantially at couplings 38. Physical junctions 48 are divided into a first junction group 66 containing all junctions J₁ and a second junction group 68 containing all junctions J₂. First junction group 66 is located on a first thermal portion 70 of substrate 30. Similarly, second junction group 68 is located on a second thermal portion 72 of substrate 30.

During operation, first thermal portion 70 (i.e., all junctions J₁) is maintained at temperature T₁ (e.g., 0° C.), and second thermal portion 72 (i.e., all junctions J₂) is maintained at temperature T₂ (e.g., 100° C.). In this manner, each thermocouple TC produces voltage E_{TC} at current I_{TC}, which together produce voltage E_{TP} at current I_{TP} as an output of PC thermopile 24.

In the preferred embodiment, all junctions J₁ in first thermal portion 70 are maintained at temperature T₁ by surrounding first thermal portion 70 of each PC thermopile 24 with a gas bath 74. The arrangement of PC thermopiles 24 in generation system 26 is desirably such that gas bath 74 may be a flow of nonconductive gas (e.g., air). gas bath 74 would therefore be able to cool (i.e., remove heat from) junctions J₁ and maintain a stable temperature T₁ thereat. The use of pins 60 (FIGS. 14 and 15) at junctions J₁ increases the mass of junctions J₁, thereby improving thermal stability. The use of heat sinks 64 on pins 60 (FIG. 15) further increases mass and significantly improves heat transfer.

Similarly, in the preferred embodiment, all junctions J₂ in second thermal portion 72 are maintained at temperature T₂ by surrounding second thermal portion 72 of each PC thermopile 24 with a liquid bath 76. The arrangement of PC thermopiles 24 in generation system 26 is desirably such that liquid bath 76 may be a flow of heated nonconductive liquid (e.g., oil). Liquid bath 76 would therefore be able to heat (i.e., pass heat into) junctions J₂ and maintain a stable temperature T₂ thereat. Again, the use of pins 60 at junctions J₂ increases the mass of junctions J₂ and improves thermal stability. The use of heat sinks 64 on pins 60 further increases mass and significantly improves heat transfer.

Those skilled in the art will appreciate that while the preferred embodiment uses gas bath 74 and liquid bath 76, this is not a requirement of the present invention. For example, two gas baths 74 at dissimilar temperatures may be used without departing from the spirit of the present invention.

Gas bath 74 and liquid bath 76 are separated by an insulator 78. Insulator 78 is desirably designed to surround each PC thermopile 24 and thermally isolate first and second portions 70 and 72.

In the preferred embodiment, liquid bath 76 is hotter than gas bath 74. This is not a requirement of the present invention, and gas and liquid baths 74 and 76 may be any desired temperatures without departing from the spirit of the present invention. For example, gas bath could be 150° C. and liquid bath could be 0° C. if those temperatures of gas and liquid are available.

Since the entirety of thermoelectric generation system 26 has no moving parts, functional life expectancy becomes essentially the life expectancy of the material used. With proper material selection, this could be decades.

Throughout this discussion it was assumed that the materials used for thermocouples TC were copper and constantan. These materials were desirable for their stability, resistance to progressive corrosion, and low cost. It will be appreciated that other materials may be desirable when other factors are considered. For example, if the requisite heat is available only in a corrosive environment, then platinum and platinum/rubidium may be desirable for thermocouples TC.

Also throughout this discussion, temperatures T₁ and T₂ were assumed to be 0° C. and 100° C., respectively (i.e., the freezing and boiling points of water). This assumption was made for convenience only, and any two dissimilar temperatures may be used. It will be appreciated that the greater the difference between temperatures T₁ and T₂, the more efficient generation system 26 will become. Also, it will be appreciated that the “cold” temperature T₁ need not be cold in the literal sense, but only colder than temperature T₂. For example, generation system 26 would operate quite well were temperature T₁ to be 100° C. and temperature T₂ to be 350° C. Naturally, proper selection of all materials (e.g., the composition of substrate 30) for the intended temperatures T₁ and T₂ would be required.

In summary, the present invention teaches a thermoelectric generation system 26 utilizing PC thermopiles 24. Though the use of PC thermopiles 24, otherwise-wasted heat derived from a natural or artificial process may be used to generate significant amounts of electrical energy. The result is a non-polluting energy source that is immune to diurnal, climatological, and meteorological effects, has no moving parts, and is readily adaptable to variant energy needs.

Although the preferred embodiments of the invention have been illustrated and described in detail, it will be readily apparent to those skilled in the art that various modifications may be made therein without departing from the spirit of the invention or from the scope of the appended claims.

1. A printed-circuit (PC) thermopile comprising:
a substrate having a first surface and a second surface, and having a first thermal portion and a second thermal portion;
a plurality of first traces, wherein each of said first traces is formed of a first metal and extends between said first thermal portion and said second thermal portion upon said first surface;
a plurality of second traces, wherein each of said second traces is formed of a second metal and extends between said first thermal portion and said second thermal portion upon said second surface;
a plurality of first junctions, wherein each of said first junctions couples one of said first traces with one of said second traces in said first thermal portion; and
a plurality of second junctions, wherein each of said second junctions couples one of said first traces with one of said second traces in said second thermal portion, and wherein each of said second junctions is in series with one of said first junctions.

2. A PC thermopile as claimed in claim 1 wherein, when said PC thermopile is in operation:
said first thermal portion is maintained at a first temperature; and
said second thermal portion is maintained at a second temperature different from said first temperature.

3. A PC thermopile as claimed in claim 2 wherein:
said first thermal portion is surrounded by a first medium at said first temperature; and
said second thermal portion is surrounded by a second medium at said second temperature.

4. A PC thermopile as claimed in claim 2 wherein:
each of said first junctions is maintained at substantially said first temperature; and
each of said second junctions is maintained at substantially said second temperature.

5. A PC thermopile as claimed in claim 1 additionally comprising a plurality of third traces, wherein each of said third traces:
passes through said substrate from said first side to said second side;
couples one of said first traces with one of said second traces; and
forms one of said first and second junctions upon one of said first and second sides.

6. A PC thermopile as claimed in claim 5 wherein:
said third metal is substantially identical to said first metal; and
said one junction is formed upon said second side.

7. A PC thermopile as claimed in claim 1 wherein:
said first metal is copper; and
said second metal is constantan.

8. A PC thermopile as claimed in claim 1 additionally comprising a plurality of conductive pins coupling one of said first traces with one of said second traces to form one of said first and second junctions.

9. A PC thermopile as claimed in claim 8 wherein said conductive pin is formed of one of said first and second metals.

10. A PC thermopile as claimed in claim 8 wherein each of said conductive pins extends into a medium surrounding said one junction.

11. A thermoelectric generation system configured to provide a predetermined voltage at a predetermined current, said system comprising:
a plurality of printed-circuit (PC) thermopiles; and
a backplane coupled to each of said PC thermopiles and configured to electrically connect said PC thermopile to provide said predetermine voltage at said predetermined current.

12. A thermoelectric generation system as claimed in claim 11 wherein each of said PC thermopiles comprises:
a substrate having a first surface and a second surface;
a plurality of first traces, wherein each of said first traces is formed of a first metal upon said first surface;
a plurality of second traces, wherein each of said second traces is formed of a second metal upon said second surface;
a plurality of first junctions, wherein each of said first junctions couples one of said first traces with one of said second traces; and
a plurality of second junctions, wherein each of said second junctions couples one of said first traces with one of said second traces, and wherein each of said second junctions is coupled in series with one of said first junctions.

13. A thermoelectric generation system as claimed in claim 12 wherein, when said system is in operation:
each of said first junctions is maintained at substantially a first temperature; and
each of said second junctions is maintained at substantially second temperature different from said first temperature.

14. A thermoelectric generation system as claimed in claim 12 wherein:
said first metal is copper; and
said second metal is constantan.

15. A thermoelectric generation system as claimed in claim 12 wherein each of said PC thermopiles additionally comprises a plurality of third traces, wherein each of said third traces couples one of said first traces with one of said second traces to form one of said first and second junctions.

16. A thermoelectric generation system as claimed in claim 15 wherein each of said third traces is formed of said first metal.

17. A thermoelectric generation system as claimed in claim 12 wherein each of said PC thermopiles additionally comprises a plurality of conductive pins, wherein each of said conductive pins couples one of said first traces with one of said second traces to form one of said first and second junctions.

18. A thermoelectric generation system as claimed in claim 11 wherein:
said predetermined voltage is a first predetermined voltage;
said predetermined current is a first predetermined current;
each of said PC thermopiles is configured to provide a second determined voltage at a second predetermined current;
said backplane is configured to electrically connect said plurality of PC thermopiles so that said second predetermined voltage from each of said PC thermopiles together produce said first predetermined voltage; and
said backplane is configured to electrically connect said plurality of PC thermopiles so that said second predetermined current from each of said PC thermopiles together produce said first predetermined current.

19. A thermoelectric generation system as claimed in claim 18 wherein:
each of said PC thermopiles comprises a plurality of thermocouples;
each of said thermocouples is configured to provide a third predetermined voltage at a third predetermined current;
each of said PC thermopiles is configured to electrically connect said plurality of thermocouples so that said third predetermined voltage from each of said thermocouples together produce said second predetermined voltage; and
each of said PC thermopiles is configured to electrically connect said plurality of thermocouples so that said third predetermined current from each of said thermocouples together produce said second predetermined current.

20. A thermoelectric generation system comprising:
a plurality of printed-circuit (PC) thermopiles, wherein each of said PC thermopiles comprises:
a substrate having a first surface and a second surface; and
a plurality of thermocouples, wherein each of said thermocouples comprises:
a first trace formed of a first metal upon said first surface of said substrate;
a second trace formed of a second metal upon said second surface of said substrate;
a first junction formed between said first and second traces and maintained at substantially a first predetermined temperature; and
a second junction formed between said first and second traces and maintained at substantially a second predetermined temperature different from said first predetermined temperature; and
a backplane coupled to each of said PC thermopiles, wherein:
each of said thermocouples is configured to provide substantially a predetermined thermocouple voltage at substantially a predetermined thermocouple current;
each of said PC thermopiles is configured to electrically connect said plurality of thermocouples so that said predetermined thermocouple voltage and current from each of said thermocouples together produce substantially a predetermined thermopile voltage at substantially a predetermined thermopile current; and
said backplane is configured to electrically connect said plurality of PC thermopiles so that said predetermined thermopile voltage and current from each of said PC thermopiles together produce a predetermined system voltage at a predetermined system current.
